(19) United States
(12) Patent Application Publication
(10) Pub. No.: US 2025/0063826 A1
(43) Pub. Date: Feb. 20, 2025

(54) PROTECTION AGAINST PLASMA INDUCED DAMAGES

(71) Applicant: Taiwan Semiconductor Manufacturing Company, Ltd., Hsinchu (TW)

(72) Inventors: Te-Chin Chang, Hsinchu County (TW); Sheng-Jier Yang, Hsinchu County (TW)

(21) Appl. No.: 18/511,666

(22) Filed: Nov. 16, 2023

Related U.S. Application Data
(60) Provisional application No. 63/519,457, filed on Aug. 14, 2023.

(51) Int. Cl. H01L 27/02

(52) U.S. Cl. CPC H01L 27/0266

(57) ABSTRACT

The present disclosure provides embodiments of semiconductor structures. A semiconductor structure according to the present disclosure includes a first transistor and a second transistor. The first transistor includes a first source feature, a first drain feature, and a first gate structure. The second transistor includes a second source feature, a second drain feature, and a second gate structure. The first source feature is electrically coupled to the second source feature and the second drain feature is electrically coupled to the first gate structure.

### PRIORITY DATA

This application claims priority to U.S. Provisional Patent Application Ser. No. 63/519,457, filed Aug. 14, 2023, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Fabrication of IC devices includes front-end-of-line (FEOL) processes and back-end-of-line (BEOL) processes. In general, the FEOL processes form transistors on a substrate and the BEOL processes form interconnect structures over or below the transistors to functionally connect the transistors. The BEOL processes include etching steps that often uses plasma. The use of plasma may generate charges that may accumulate at electrically isolated nodes during BEOL processes. When sufficient charges are accumulated, the energy may be dissipated on a single spot of a gate dielectric layer. This may cause breakdown of the gate dielectric layer and permanent damages to the transistor. These damages may be referred to as plasma-induced damages (PIDs). Several techniques have been proposed to prevent or reduce PIDs.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit diagram of a first type PID prevention device, according to various aspects of the present disclosure.

FIG. 2 illustrates a schematic cross-sectional view of the first PID prevention device implemented with transistors having insulated source/drain features, according to various aspects of the present disclosure.

FIG. 3 illustrates a schematic cross-sectional view of the first PID prevention device implemented with transistors having backside contact structures, according to various aspects of the present disclosure.

FIG. 4 is a circuit diagram of a second PID prevention device, according to various aspects of the present disclosure.

FIG. 5 illustrates a schematic cross-sectional view of the second PID prevention device implemented with transistors having insulated source/drain features, according to various aspects of the present disclosure.

FIG. 6 illustrates a schematic cross-sectional view of the second PID prevention device implemented with transistors having backside contact structures, according to various aspects of the present disclosure.

FIG. 7 is a circuit diagram of a third PID prevention device, according to various aspects of the present disclosure.

FIG. 8 illustrates a schematic cross-sectional view of the third PID prevention device implemented with transistors having insulated source/drain features, according to various aspects of the present disclosure.

FIG. 9 illustrates a schematic cross-sectional view of the third PID prevention device implemented with transistors having backside contact structures, according to various aspects of the present disclosure.

FIG. 10 is a circuit diagram of a fourth PID prevention device, according to various aspects of the present disclosure.

FIG. 11 illustrates a schematic cross-sectional view of the fourth PID prevention device implemented with transistors having insulated source/drain features, according to various aspects of the present disclosure.

FIG. 12 illustrates a schematic cross-sectional view of the fourth PID prevention device implemented with transistors having backside contact structures, according to various aspects of the present disclosure.

FIG. 13 is a circuit diagram of a fifth PID prevention device, according to various aspects of the present disclosure.

FIG. 14 illustrates a schematic cross-sectional view of the fifth PID prevention device implemented with transistors having insulated source/drain features, according to various aspects of the present disclosure.

FIG. 15 illustrates a schematic cross-sectional view of the fifth PID prevention device implemented with transistors having backside contact structures, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art.

Fabrication of IC devices includes front-end-of-line (FEOL) processes and back-end-of-line (BEOL) processes. In general, the FEOL processes form transistors on a substrate and the BEOL processes form interconnect structures over or below the transistors to functionally connect the transistors. The interconnect structures include several layer of metal layers, each of which may include metal lines and contact vias. Formation of these metal lines and contact via may include use of dry etch processes that are aided by plasma. As more and more metal lines and contact vias are formed, they may inevitably serve as an antenna to collect charges generated by incident of plasma. When sufficient charge is accumulated at an electrically isolated node, the charge may cause high-field stress on dielectric features, such as a gate dielectric layer. The stress may cause damages to the transistors. For example, when this happens to a gate dielectric layer, the high-field stress may cause breakdown of the gate dielectric layer and total failure of the transistor. This type of damages may be generally referred to as plasma-induced damages (PIDs). Various techniques have been developed to prevent or alleviate PIDs. In some practices, a conduction path to an electrical ground is established for the charge collected by the metal wiring antenna. However, such a conduction path may not be readily available in some situations.

The present disclosure provides embodiments of PID prevention devices that disperse harmful accumulation of charges. The PID prevention devices of the present disclosure include an antenna transistor that is electrically coupled to a protected device. In some embodiments, the antenna transistor provides a conduction path to discharge the accumulated charge. In some embodiments, the antenna transistor is similarly situated with the protected device to share the high-field stresses induced by the plasma.

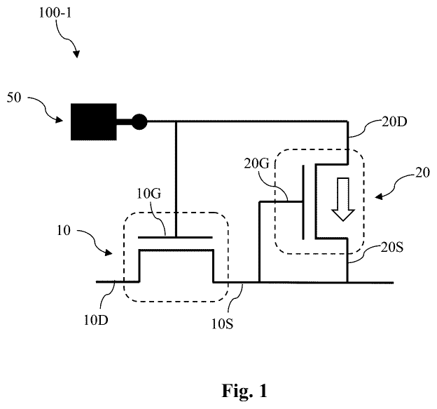

The following description are provided in conjunction with the illustration in FIGS. 1-15. Throughout the disclosure, like reference numerals denote like features and may indicate similar compositions or formation processes unless otherwise described. For that reason, features with the same reference numerals may only be described once for simplicity. The X, Y, and Z directions are used consistently throughout the figures and the Z direction may be referred to as the vertical direction. As used herein, source/drain region(s) or source/drain feature(s) may refer to a source or a drain, individually or collectively, dependent upon the context.

Reference is first made to FIG. 1, which is a circuit diagram of a first PID prevention device 100-1. As shown in FIG. 1, the first PID prevention device 100-1 is configured to protect a protected transistor 10 that includes a first gate 10G, a first drain 10D, and a first source 10S. The first PID prevention device 100-1 includes an antenna transistor 20 that includes a second gate 20G, a second drain 20D, and a second source 20S. In the embodiments depicted in FIG. 1, the second gate 20G and the second source 20S are electrically coupled to the first source 10S while the second drain 20D is electrically coupled to the first gate 10G. The first gate 10G, along with the second drain 20D, is electrically coupled to a metal wiring structure 50. The metal wiring structure 50 may be part of a frontside interconnect structure and is in position to accumulate charges generated by plasma. When the metal wiring structure 50 functions as an antenna to collect charges, the charges may flow to the first source 10S and the second source 20S both by way of leakage through the first gate 10G and by way of the leakage path between the second drain 20D and the second source 20S. It can be seen that the leakage path between the second drain 20D and the second source 20S discharges the accumulated charge and reduces the high-field stress at the first gate 10G. The dispersion of charges reduces the probability of damages to the protected transistor 10. When the first gate 10G is turned on during operation, the antenna transistor 20 is turned off. Because the antenna transistor 20 is turned off during operation, the first PID prevention device 100-1 is designed to minimize leakage current (I_{D}).

The first PID prevention device 100-1 illustrated in FIG. 1 and other PID prevention devices described herein may be implemented with different types of planar transistors or multi-gate transistors. A multi-gate device generally refers to a device having a gate structure, or portion thereof, disposed over more than one side of a channel region. Fin-like field effect transistors (FinFETs) and Gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT). Because the channel region of an GAA transistor may include nanowires or nanosheets and its configuration resembles a bridge, a GAA transistor may also be referred to a multi-bridge-channel (MBC) transistor, a nanowire transistor, or a nanosheet transistor. The nanosheets and nanowires may be generally referred to as nanostructures. The first PID prevention device 100-1 illustrated in FIG. 1 may also be implemented using transistors with a stacked device configuration. For example, it may be implemented using complementary field effect transistors (C-FET) where multi-gate transistors are stacked vertically, one over another. For illustration purposes, implementation of the first PID prevention device 100-1 and other PID prevention devices of the present disclosure will be described using GAA transistors as an example.

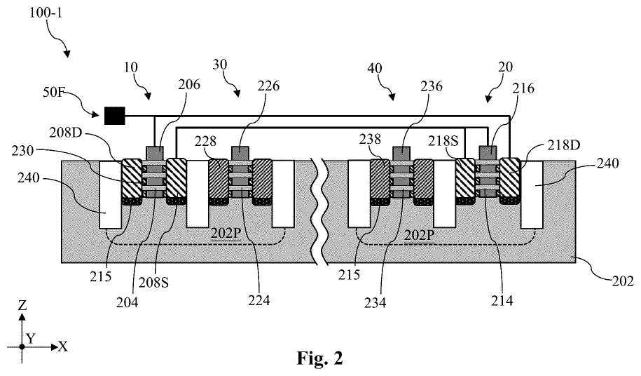

FIG. 2 illustrates a schematic cross-sectional view of the first PID prevention device 100-1 implemented with GAA transistors having insulated source/drain features. The protected transistor 10 in FIG. 2 is a GAA transistor that including first channel members 204 extending between a first source feature 208S and a first drain feature 208D along the X direction. A first gate structure 206 wraps around each of the first channel members 204. In the depicted embodiments, the protected transistor 10 is an n-type GAA transistor disposed over a first p-type well 202P of a substrate 202. In some instances, the first p-type well 202P may include a p-type dopant, such as boron (B). The first source feature 208S and the first drain feature 208 include silicon (Si) and an n-type dopant, such as phosphorus (P) or arsenic (As). The first source feature 208S and the first drain feature 208 of the protected transistor 10 are not in direct contact with the first p-type well 202P. As shown in FIG. 2, each of the first source feature 208S and the first drain feature 208 is insulated from the p-type well 202P by a bottom isolation layer 215. In some instances, the bottom isolation layer 215 may include silicon nitride, silicon oxide, silicon oxynitride, or silicon oxycarbonitride. In one embodiment, the bottom isolation layer 215 includes silicon nitride. A plurality of inner spacer features 230 interleave the first channel members 204 and space the first gate structure 206 from sidewalls of the first source feature 208S and the first drain feature 208D.

Although not explicitly shown in FIG. 2, the first gate structure 206 includes a gate dielectric layer and a gate electrode layer. In some embodiments, the gate dielectric layer may include an interfacial layer and a high-k dielectric layer. Here, high-k dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include hafnium oxide. Alternatively, the high-k dielectric layer may include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer of the first gate structure 206 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process.

As illustrated in FIG. 2, the first PID prevention device 100-1 includes an antenna transistor 20 that is structurally similar to the protected transistor 10. The antenna transistor 20 is also an n-type GAA transistor disposed on a second p-type well 202P different from the first p-type well 202P. Like the protected transistor 10, the antenna transistor 20 includes second channel members 214 extending between a second source feature 218S and a second drain feature 218D along the X direction. A second gate structure 216 wraps around each of the second channel members 214. The second source feature 218S and the second drain feature 218D are n-type and include silicon (Si) and an n-type dopant, such as phosphorus (P) or arsenic (As).

In some embodiments represented in FIG. 2, the second source feature 218S is electrically coupled to the first source feature 208S, the second drain feature 218D is electrically coupled to the first gate structure 206. Additionally, the second gate structure 216 is not left electrically floating but is electrically coupled to the second source feature 218S and the first source feature 208S. The first gate structure 206 and the second drain feature 218D are electrically coupled to a group of frontside metal wiring structure 50F, which may collect accumulated charges to cause damages to the protected transistor 10. When connected in the way shown in FIG. 2, the accumulated charge may be discharged through either the first gate structure 206 or through the leakage path between the second drain feature 218D and the second source feature 218S. The leakage path of the antenna transistor 20 helps reduce or eliminate the high-field stress at the first gate structure 106.

Tap cells are common in standard cell designs and may be inserted into an IC device to serve as ways to pull the p-type wells 202P to a ground voltage (Vss). While the adoption of the bottom isolation layers 215 may render tap cells useless, tap cell structures may still be present. In some embodiments represented in FIG. 2, a first tap cell transistor 30 shares the same first p-type well 202P with the protected transistor 10 and a second tap cell transistor 40 shares the same second p-type well 202P with the antenna transistor 20. It can be seen that, when the bottom isolation layer 215 is not present, the first tap cell transistor 30 serves as an access point to the first p-type well 202P and the second tap cell transistor 40 serves as an access point to the second p-type well 202P. The first tap cell transistor 30 is similar to a p-type GAA transistor. As shown in FIG. 2, the first tap cell transistor 30 includes third channel members 224 extending between third source/drain features 228 and a third gate structure 226 wrapping around each of the third channel members 224. The third source/drain features 228 are p-type and include silicon germanium (SiGe) and a p-type dopant, such as boron (B). The third gate structure 226 and the third source/drain features 228 are all electrically floating, not electrically coupled to the protected transistor 10, the antenna transistor 20, or the interconnect structures. The second tap cell transistor 40 is the same way. The second tap cell transistor 40 is similar to a p-type GAA transistor. The second tap cell transistor 40 includes fourth channel members 234 extending between fourth source/drain features 238 and a fourth gate structure 236 wrapping around each of the fourth channel members 234. The fourth source/drain features 238 are p-type and include silicon germanium (SiGe) and a p-type dopant, such as boron (B). The fourth gate structure 236 and the fourth source/drain features 238 are all electrically floating, not electrically coupled to the protected transistor 10, the antenna transistor 20, or the interconnect structures. Because the first tap cell transistor 30 and the second tap cell transistor 40 do not serve tap cell functions anymore, they may be referred to as dummy transistors. In some embodiments, they may be entirely omitted to reduce device footprint and standard cell dimensions. In some embodiments represented in FIG. 2, the different transistors may be isolated from each other by isolation features 240. The isolation features 240 may include dielectric materials such as silicon oxide, silicon nitride, silicon oxynitride, or silicon oxycarbonitride.

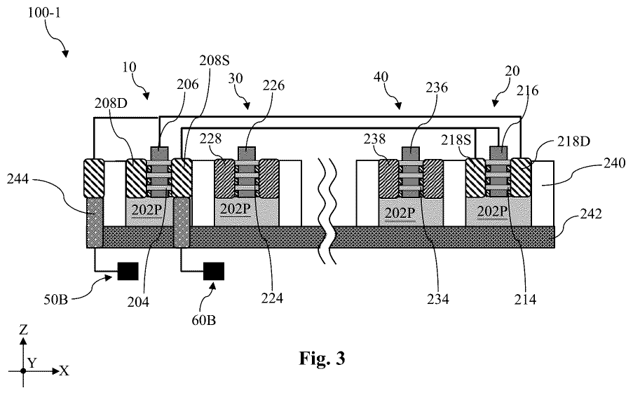

FIG. 3 illustrates a schematic cross-sectional view of the first PID prevention device 100-1 implemented with GAA transistors having backside contact structures. The protected transistor 10 in FIG. 3 is a GAA transistor that including first channel members 204 extending between a first source feature 208S and a first drain feature 208D. A first gate structure 206 wraps around each of the first channel members 204. In the depicted embodiments, the protected transistor 10 is an n-type GAA transistor disposed over a first p-type well 202P of a substrate 202. Different from the embodiment illustrated in FIG. 2, GAA transistors in FIG. 3 have a super power rail (SPR) construction, where backside contacts 244 extend through a backside dielectric layer 242 to couple the first source feature 208S to a backside interconnect structure. As shown in FIG. 3, the backside dielectric layer 242 is deposited after the substrate 202 (not explicitly shown in FIG. 3) is thinned until different well regions (such as the p-type wells 202P) are physically and electrically insulated from each other. Due to the SPR construction, there is no common bulk substrate or common well regions to serve as an electrical ground.

As shown in FIG. 3, the protected transistor 10 includes first channel members 204 extending between the first source feature 208S and the first drain feature 208 along the X direction. Each of the first source feature 208S and the first drain feature 208D is disposed on a first p-type well 202P. The antenna transistor 20 in FIG. 3 is structurally similar to the protected transistor 10. The antenna transistor 20 is also an n-type GAA transistor disposed on a second p-type well 202P different from the first p-type well 202P. Like the protected transistor 10, the antenna transistor 20 includes second channel members 214 extending between a second source feature 218S and a second drain feature 218D along the X direction. A second gate structure 216 wraps around each of the second channel members 214. Details of the first p-type well 202P, the first source feature 208S, the first drain feature 208D, the second source feature 218S, the second drain feature 218D, the first gate structure 206, and the second gate structure 216 have been described above in conjunction with FIG. 2 and will not be repeated here for brevity.

In some embodiments represented in FIG. 3, the second source feature 218S is electrically coupled to the first source feature 208S, the second drain feature 218D is electrically coupled to the first drain feature 208D. Additionally, the second gate structure 216 is not left electrically floating but is electrically coupled to the second source feature 218S and the first source feature 208S. The first gate structure 206 and the second drain feature 218D are electrically coupled to a first group of backside metal wiring structure 50B by way of a backside contact 244. The first group of backside metal wiring structure 50B may collect accumulated charges to cause damages to the protected transistor 10. The first source feature 208S is coupled to a second group of backside metal wiring structure 60B by way of a backside contact 244. When connected in the way shown in FIG. 3, the accumulated charge in the first group of backside metal wiring structure 50B may be discharged to the second group of backside metal wiring structure 60B through either the first gate structure 206 or through the leakage path between the second drain feature 218D and the second source feature 218S. The leakage path of the antenna transistor 20 helps reduce or eliminate the high-field stress at the first gate structure 106.

As described above, tap cells are common in standard cell designs and may be inserted into an IC device to serve as ways to pull the p-type wells 202P to a ground voltage (Vss). While the adoption of the SPR construction may render tap cells useless, tap cell structures may still be present. In some embodiments represented in FIG. 3, a first tap cell transistor 30 is disposed over a third p-type well 202P and a second tap cell transistor 40 is disposed on a fourth p-type well 202P. The first tap cell transistor 30 is similar to a p-type GAA transistor. As shown in FIG. 3, the first tap cell transistor 30 includes third channel members 224 extending between third source/drain features 228 and a third gate structure 226 wrapping around each of the third channel members 224. The third source/drain features 228 are p-type and include silicon germanium (SiGe) and a p-type dopant, such as boron (B). The third gate structure 226 and the third source/drain features 228 are all electrically floating, not electrically coupled to the protected transistor 10, the antenna transistor 20, or the interconnect structures. The second tap cell transistor 40 is the same way. The second tap cell transistor 40 is similar to a p-type GAA transistor. The second tap cell transistor 40 includes fourth channel members 234 extending between fourth source/drain features 238 and a fourth gate structure 236 wrapping around each of the fourth channel members 234. The fourth source/drain features 238 are p-type and include silicon germanium (SiGe) and a p-type dopant, such as boron (B). The fourth gate structure 236 and the third source/drain features 238 are all electrically floating, not electrically coupled to the protected transistor 10, the antenna transistor 20, or the interconnect structures. Because the p-type wells are all isolated from one another, the first tap cell transistor 30 and the second tap cell transistor 40 do not serve tap cell functions anymore and may be referred to as dummy transistors. In some embodiments, they may be entirely omitted to reduce device footprint and standard cell dimensions. In some embodiments represented in FIG. 3, the different transistors may also be isolated from each other along the X direction by isolation features 240.

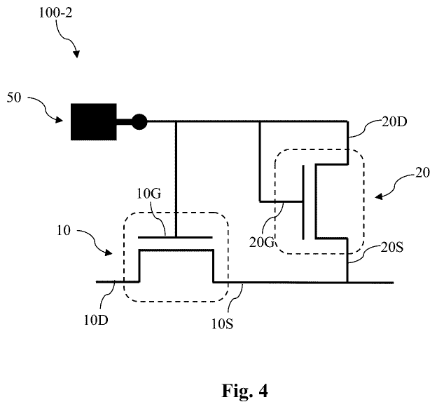

Reference is now made to FIG. 4, which is a circuit diagram of a second PID prevention device 100-2. The second PID prevention device 100-2 is similar to the first PID prevention device 100-1 except that the second gate 20G is electrically coupled to the second drain 20D, the first gate 10G and the frontside metal wiring structure 50F. Due to the similarity with the first PID prevention device 100-1 and the second PID prevention device 100-2, detailed description of the circuit diagram of the second PID prevention device 100-2 is omitted for brevity. When the first gate 10G in FIG. 4 is turned on during operation, the antenna transistor 20 is also turned on. When the second PID prevention device 100-2 is adopted, the design of the IC device should take the leakage current (I_{D}) into consideration.

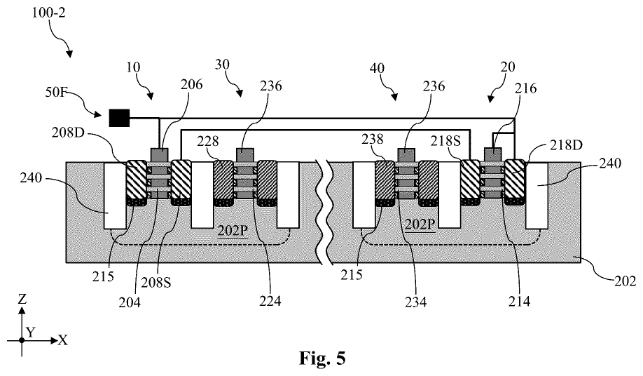

FIG. 5 illustrates a schematic cross-sectional view of the second PID prevention device 100-2 implemented with GAA transistors having insulated source/drain features. The second PID prevention device 100-2 in FIG. 5 is similar to the first PID prevention device 100-1 in FIG. 2 except that the second gate structure 216 is electrically coupled to the second drain feature 218D, the first gate structure 206, and the frontside metal wiring structure 50F. Due to the similarity with the first PID prevention device 100-1 in FIG. 2 and the second PID prevention device 100-2 in FIG. 5, detailed description of the various features in FIG. 5 is omitted for brevity.

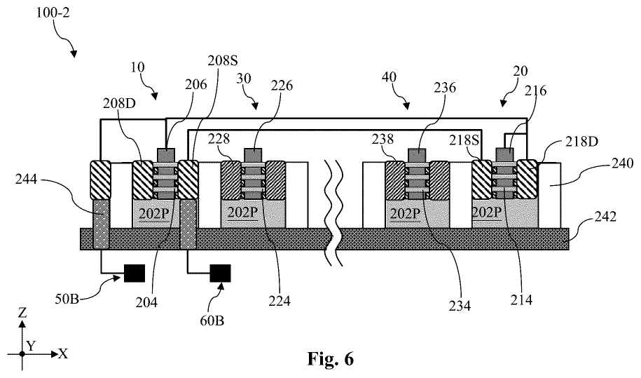

FIG. 6 illustrates a schematic cross-sectional view of the second PID prevention device 100-2 implemented with GAA transistors having backside contact structures. The second PID prevention device 100-2 in FIG. 6 is similar to the first PID prevention device 100-1 in FIG. 2 except that the second gate structure 216 is electrically coupled to the second drain feature 218D, the first gate structure 206, and the first group of backside metal wiring structure 50B. Due to the similarity with the first PID prevention device 100-1 in FIG. 3 and the second PID prevention device 100-2 in FIG. 6, detailed description of the various features in FIG. 6 is omitted for brevity.

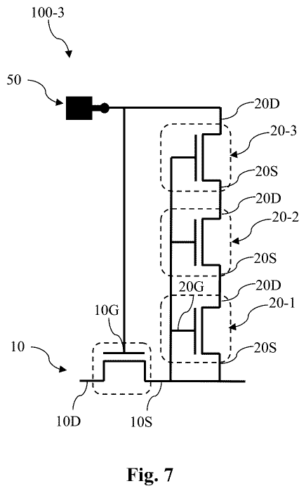

Reference is made to FIG. 7, which is a circuit diagram of a third PID prevention device 100-3. In some embodiments, the drain-to-source leakage path of the antenna transistor 20 may not have sufficient resistance to reduce the leakage current. To remedy this concern, more than one antenna transistor 20 may be connected in a stacked gate configuration to connect the leakage paths of these antenna transistors 20 in series. In some embodiments illustrated in FIG. 7, three antenna transistors 20, which include a first antenna transistor 20-1, a second antenna transistor 20-2 and a third antenna transistor 20-3, are connected in a stacked gate configuration. While 3 antenna transistors 20 are shown in FIG. 7 for illustration purposes, more than three antenna transistors 20 may be connected in a stacked gate configuration to serve as the third PID prevention device 100-3. In some instances, the number of antenna transistors in the third PID prevention device 100-3 may be between 2 and 1000.

Reference is still made to FIG. 7. In a stacked gate configuration, the second source 20S of the first antenna transistor 20-1 is electrically coupled to the first source 10S and the second drain 20D of the first antenna transistor 20-1 is electrically coupled to the second source 20S of the second antenna transistor 20-2. Similarly, a second drain 20D of the second antenna transistor 20-2 is electrically coupled to the second source 20S of the third antenna transistor 20-3. Finally, the second drain 20D of the third antenna transistor 20-3 is electrically coupled to the first gate 10G and the metal wiring structure 50. The second gates 20G of the first antenna transistor 20-1, the second antenna transistor 20-2 and the third antenna transistor 20-3 are electrically coupled to the first source 10S of the protected transistor 10. The metal wiring structure 50 may be part of a frontside interconnect structure and is in position to accumulate charges generated by contact with plasma. When the metal wiring structure 50 functions as an antenna to collect charges, the charges may flow to the first source 10S and the second source 20S both by way of leakage through the first gate 10G and by way of the serial leakage path between the along the second drains 20D and the second sources 20S of the first antenna transistor 20-1, the second antenna transistor 20-2 and the third antenna transistor 20-3. It can be seen that the serial leakage path discharges the accumulated charge and reduces the high-field stress at the first gate 10G. The dispersion of charges reduces the probability of damages to the protected transistor 10. Additionally, the serial leakage path among the antenna transistors 20-1, 20-2 and 20-3 has a greater resistance, which may reduce the leakage current. When the first gate 10G in FIG. 7 is turned on during operation, the first antenna transistor 20-1, the second antenna transistor 20-2 and the third antenna transistor 20-3 are turned off. Because the antenna transistors are turned off during operation, the third PID prevention device 100-3 is designed to minimize leakage current (I_{D}).

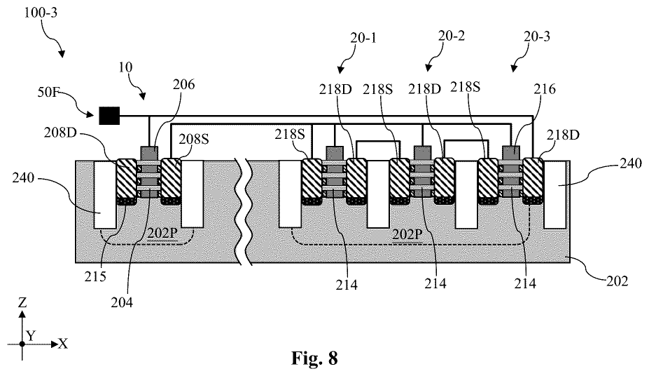

FIG. 8 illustrates a schematic cross-sectional view of the third PID prevention device 100-3 implemented with GAA transistors having insulated source/drain features. The protected transistor 10 in FIG. 8 is a GAA transistor that including first channel members 204 extending between a first source feature 208S and a first drain feature 208D. A first gate structure 206 wraps around each of the first channel members 204. In the depicted embodiments, the protected transistor 10 is an n-type GAA transistor disposed over a first p-type well 202P of a substrate 202. The first source feature 208S and the first drain feature 208 of the protected transistor 10 are not in direct contact with the first p-type well 202P. As shown in FIG. 8, each of the first source feature 208S and the first drain feature 208 is insulated from the p-type well 202P by a bottom isolation layer 215. A plurality of inner spacer features 230 interleave the first channel members 204 and space the first gate structure 206 from sidewalls of the first source feature 208S and the first drain feature 208D. Detailed description of the first p-type well 202P, the first source feature 208S, the first drain feature 208D, the first gate structure 206, and inner spacer features 230 have been provided above and will not be repeated here for brevity.

Instead of having a single antenna transistor 20 as in the first PID prevention device 100-1 in FIG. 2, the third PID prevention device 100-3 includes multiple antenna transistors connected in a stacked gate configuration. For illustration purposes, the third PID prevention device 100-3 in FIG. 8 includes three antenna transistors—a first antenna transistor 20-1, a second antenna transistor 20-2 and a third antenna transistor 20-3. Each of the three antenna transistors includes second channel members 214 extending between a second source feature 218S and a second drain feature 218D. A second gate structure 216 wraps around each of the second channel members 214. In the depicted embodiments, each of the first antenna transistor 20-1, the second antenna transistor 20-2 and the third antenna transistor 20-3 is an n-type GAA transistor disposed on a second p-type well. In some alternative embodiments, the first antenna transistor 20-1, the second antenna transistor 20-2 and the third antenna transistor 20-3 may be disposed over different p-type wells.

In some embodiments represented in FIG. 8, the second source feature 218S of the first antenna transistor 20-1 is electrically coupled to the first source feature 208S. The second drain feature 218D of the first antenna transistor 20-1 is electrically coupled to the second source feature 218S of the second antenna transistor 20-2. The second drain feature 218D of the second antenna transistor 20-2 is electrically coupled to the second source feature 218S of the third antenna transistor 20-3. The second drain feature 218D of the third antenna transistor 20-3 is electrically coupled to the first gate structure 206 and a group of frontside metal wiring structure 50F, which may collect accumulated charges to cause damages to the protected transistor 10. Additionally, second gate structures 216 of the first antenna transistor 20-1, the second antenna transistor 20-2 and the third antenna transistor 20-3 are electrically coupled together and to the second source feature 218S of the first antenna transistor 20-1 and the first source feature 208S. When connected in the way shown in FIG. 8, the accumulated charge may be discharged through either the first gate structure 206 or through the serial leakage path between the second drain feature 218D of the third antenna transistor 20-3 and the second source feature 218S of the first antenna transistor 20-1. The serial leakage path of the antenna transistor 20 helps reduce or eliminate the high-field stress at the first gate structure 106.

Tap cells are common in standard cell designs and may be inserted into an IC device to serve as ways to pull the p-type wells 202P to a ground voltage (Vss). While the adoption of the bottom isolation layer 215 may render tap cells useless, tap cell structures may still be present. In some embodiments represented in FIG. 8, tap cell transistors are omitted. In some alternative embodiments, tap cell transistors may be inserted between the protected transistor 10 and the first antenna transistor 20-1. Details of the tap cell transistors in these alternative embodiments have been described above and will not be repeated here.

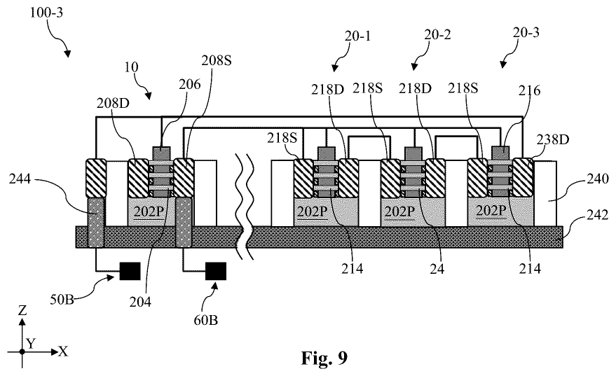

FIG. 9 illustrates a schematic cross-sectional view of the third type PID prevention device 100-3 implemented with GAA transistors having backside contact structures. The protected transistor 10 in FIG. 9 is a GAA transistor that including first channel members 204 extending between a first source feature 208S and a first drain feature 208D along the X direction. A first gate structure 206 wraps around each of the first channel members 204. A plurality of inner spacer features 230 interleave the first channel members 204 and space the first gate structure 206 from sidewalls of the first source feature 208S and the first drain feature 208D. In the depicted embodiments, the protected transistor 10 is an n-type GAA transistor disposed over a first p-type well 202P of a substrate 202. The first source feature 208S and the first drain feature 208 of the protected transistor 10 are in direct contact with the first p-type well 202P but the first p-type well 202P is insulated from other well regions. As shown in FIG. 9, the protected transistor 10 includes a SPR construction where the substrate is thinned such that neither a bulk substrate nor a common well is available to connect two well regions. Backside contacts 244 are formed through a backside dielectric layer 242 to couple to source/drain features, such as the first source feature 208S. Detailed description of the first p-type well 202P, the first source feature 208S, the first drain feature 208D, the first gate structure 206, and inner spacer features 230 have been provided above and will not be repeated here for brevity.

Instead of having a single antenna transistor 20 as in the first PID prevention device 100-1 in FIG. 3, the third PID prevention device 100-3 in FIG. 9 includes multiple antenna transistors connected in a stacked gate configuration. For illustration purposes, the third PID prevention device 100-3 in FIG. 8 includes three antenna transistors—a first antenna transistor 20-1, a second antenna transistor 20-2 and a third antenna transistor 20-3. Each of the three antenna transistors includes second channel members 214 extending between a second source feature 218S and a second drain feature 218D. A second gate structure 216 wraps around each of the second channel members 214. In the depicted embodiments, each of the first antenna transistor 20-1, the second antenna transistor 20-2 and the third antenna transistor 20-3 is an n-type GAA transistor disposed on separate p-type wells.

In some embodiments represented in FIG. 9, the second source feature 218S of the first antenna transistor 20-1 is electrically coupled to the first source feature 208S. The second drain feature 218D of the first antenna transistor 20-1 is electrically coupled to the second source feature 218S of the second antenna transistor 20-2. The second drain feature 218D of the second antenna transistor 20-2 is electrically coupled to the second source feature 218S of the third antenna transistor 20-3. The second drain feature 218D of the third antenna transistor 20-3 is electrically coupled to the first gate structure 206 and a group of frontside metal wiring structure 50F, which may collect accumulated charges to cause damages to the protected transistor 10. Additionally, second gate structures 216 of the first antenna transistor 20-1, the second antenna transistor 20-2 and the third antenna transistor 20-3 are electrically coupled together and to the second source feature 218S of the first antenna transistor 20-1 and the first source feature 208S. The first gate structure 206 and the second drain feature 218D of the third antenna transistor 20-3 are electrically coupled to the second source feature 218S of the first antenna transistor 20-1 and the first source feature 208S. The first gate structure 206 and the second drain feature 218D of the third antenna transistor 20-3 are electrically coupled to a first group of backside metal wiring structure 50B by way of a backside contact 244. The first group of backside metal wiring structure 50B may collect accumulated charges to cause damages to the protected transistor 10. The first source feature 208S is coupled to a second group of backside metal wiring structure 60B by way of a backside contact 244. When connected in the way shown in FIG. 9, the accumulated charge in the first group of backside metal wiring structure 50B may be discharged to the second group of backside metal wiring structure 60B through either the first gate structure 206 or through the serial leakage path between the second drain feature 218D of the third antenna transistor 20-3 and the second source feature 218S of the first antenna transistor 20-1. The serial leakage path of the antenna transistors 20 helps reduce or eliminate the high-field stress at the first gate structure 106.

Tap cells are common in standard cell designs and may be inserted into an IC device to serve as ways to pull the p-type wells 202P to a ground voltage (Vss). While the adoption of the SPR construction may render tap cells useless, tap cell structures may still be present. In some embodiments represented in FIG. 9, tap cell transistors are omitted. In some alternative embodiments, tap cell transistors may be inserted between the protected transistor 10 and the first antenna transistor 20-1. Details of the tap cell transistors in these alternative embodiments have been described above and will not be repeated here.

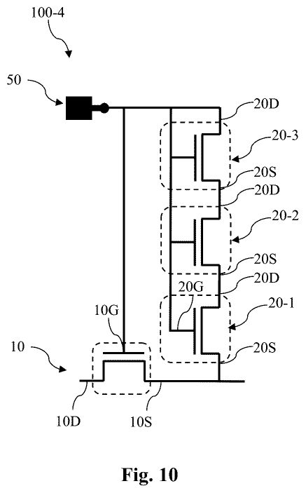

Reference is made to FIG. 10, which is a circuit diagram of a fourth PID prevention device 100-4. The fourth PID prevention device 100-4 is similar to the third PID prevention device 100-3 except that the second gates 20G of the first antenna transistor 20-1, the second antenna transistor 20-2 and the third antenna transistor 20-3 are electrically coupled to the second drain 20D, the first gate 10G and the metal wiring structure 50. Due to the similarity with the third PID prevention device 100-3 and the fourth PID prevention device 100-4, detailed description of the circuit diagram of the fourth PID prevention device 100-4 is omitted for brevity. When the first gate 10G in FIG. 10 is turned on during operation, the first antenna transistor 20-1, the second antenna transistor 20-2 and the third antenna transistor 20-3 are also turned on. Therefore, when the fourth PID prevention device 100-4 is adopted, the design of the IC device should take the leakage current (I_{D}) into consideration.

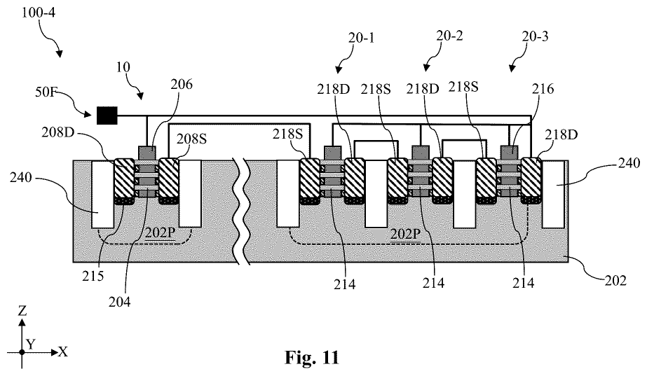

FIG. 11 illustrates a schematic cross-sectional view of the fourth PID prevention device 100-4 implemented with GAA transistors having insulated source/drain features. The fourth PID prevention device 100-4 in FIG. 11 is similar to the third PID prevention device 100-3 in FIG. 8 except that the second gate structures 216 of the first antenna transistor 20-1, the second antenna transistor 20-2 and the third antenna transistor 20-3 are electrically coupled to the second drain feature 218D of the third antenna transistor, the first gate structure 206, and the group of frontside metal wiring structure 50F. Due to the similarity with fourth first PID prevention device 100-4 in FIG. 11 and the third PID prevention device 100-3 in FIG. 8, detailed description of the various features in FIG. 11 is omitted for brevity.

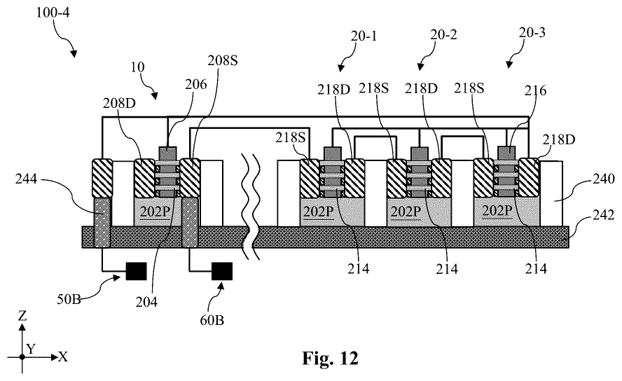

FIG. 12 illustrates a schematic cross-sectional view of the fourth PID prevention device 100-4 implemented with GAA transistors having backside contact structures. The fourth PID prevention device 100-4 in FIG. 12 is similar to the third PID prevention device 100-3 in FIG. 9 except that the second gate structures 216 of the first antenna transistor 20-1, the second antenna transistor 20-2 and the third antenna transistor 20-3 are electrically coupled to the second drain feature 218D of the third antenna transistor 20-3, the first gate structure 206, and the first group of backside metal wiring structure 50B. Due to the similarity with the fourth PID prevention device 100-4 in FIG. 12 and the third PID prevention device 100-3 in FIG. 9, detailed description of the various features in FIG. 12 is omitted for brevity.

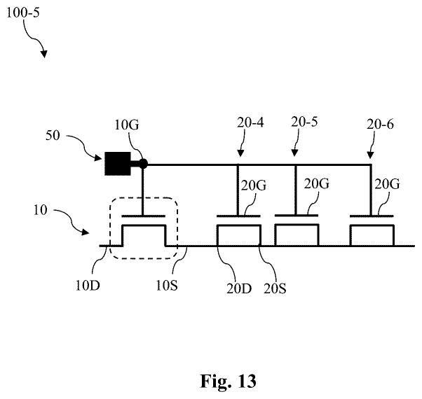

Reference is then made to FIG. 13, which is a circuit diagram of a fifth PID prevention device 100-5. As shown in FIG. 1, the first PID prevention device 100-1 is configured to protect a protected transistor 10 that includes a first gate 10G, a first drain 10D, and a first source 10S. The fifth PID prevention device 100-5 includes multiple antenna transistors connected in a multi-finger configuration between the first gate 10G and the first source 10S of a protected transistor 10. While the number of antenna transistors in the fifth PID prevention device 100-5 may be between 2 and 1000, three antenna transistors are shown in FIG. 13 for illustration purposes. The three antenna transistors in FIG. 13 include a fourth antenna transistor 20-4, a fifth antenna transistor 20-5 and a sixth antenna transistor 20-6. Each of the fourth antenna transistor 20-4, the fifth antenna transistor 20-5 and the sixth antenna transistor 20-6 includes a second gate 20G, a second drain 20D, and a second source 20S. In the embodiments depicted in FIG. 13, the second gates 20G of the fourth antenna transistor 20-4, the fifth antenna transistor 20-5 and the sixth antenna transistor 20-6 are electrically coupled to the first gate 10G and the metal wiring structure 50. All second sources 20S and second drains 20D are electrically coupled to the first source 10S. The metal wiring structure 50 may be part of a frontside interconnect structure and is in position to accumulate charges generated by contact with plasma. When the metal wiring structure 50 functions as an antenna to collect charges, the charges may apply a field stress that is shared by the first gate 10G and all of the second gates 20G. It can be seen that the distribution or dispersion of the high-field stress reduces the high-field stress at the first gate 10G. It can also be seen that when there are more antenna transistors in the fifth PID prevention device 100-5, the first gate 10G is under smaller field stress.

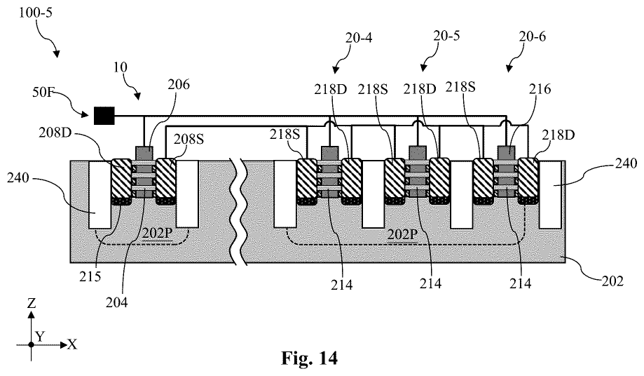

FIG. 14 illustrates a schematic cross-sectional view of the fifth PID prevention device 100-5 implemented with GAA transistors having insulated source/drain features. The protected transistor 10 in FIG. 14 is a GAA transistor that including first channel members 204 extending between a first source feature 208S and a first drain feature 208D along the X direction. A first gate structure 206 wraps around each of the first channel members 204. In the depicted embodiments, the protected transistor 10 is an n-type GAA transistor disposed over a first p-type well 202P of a substrate 202. The first source feature 208S and the first drain feature 208 of the protected transistor 10 are not in direct contact with the first p-type well 202P. As shown in FIG. 13, each of the first source feature 208S and the first drain feature 208 is insulated from the p-type well 202P by a bottom isolation layer 215. A plurality of inner spacer features 230 interleave the first channel members 204 and space the first gate structure 206 from sidewalls of the first source feature 208S and the first drain feature 208D. Detailed description of the first p-type well 202P, the first source feature 208S, the first drain feature 208D, the first gate structure 206, and inner spacer features 230 have been provided above and will not be repeated here for brevity.

The fifth PID prevention device 100-5 in FIG. 14 includes multiple antenna transistors connected in a stacked gate configuration. For illustration purposes, the fifth PID prevention device 100-5 in FIG. 14 includes three antenna transistors—a fourth antenna transistor 20-4, a fifth antenna transistor 20-5 and a sixth antenna transistor 20-6. Each of the three antenna transistors includes second channel members 214 extending between a second source feature 218S and a second drain feature 218D. A second gate structure 216 wraps around each of the second channel members 214. In the depicted embodiments, each of the fourth antenna transistor 20-4, the fifth antenna transistor 20-5 and the sixth antenna transistor 20-6 is an n-type GAA transistor disposed on a second p-type well. In some alternative embodiments, the fourth antenna transistor 20-4, the fifth antenna transistor 20-5 and the sixth antenna transistor 20-6 may be disposed over different p-type wells.

In some embodiments represented in FIG. 14, the second source features 218S and second drain features 218D of the fourth antenna transistor 20-4, the fifth antenna transistor 20-5 and the sixth antenna transistor 20-6 are electrically coupled to the first source feature 208S. The second gate structures 216 of the fourth antenna transistor 20-4, the fifth antenna transistor 20-5 and the sixth antenna transistor 20-6 are electrically coupled to the first gate structure 206 and a group of frontside metal wiring structure 50F. When connected in the way shown in FIG. 14, the accumulated charge from the frontside metal wiring structure 50F may cause a field stress shared among the first gate structure 206 and the second gate structures 216 of the fourth antenna transistor 20-4, the fifth antenna transistor 20-5 and the sixth antenna transistor 20-6. The distribution of field stress helps reduce or eliminate the high-field stress at the first gate structure 106.

Tap cells are common in standard cell designs and may be inserted into an IC device to serve as ways to pull the p-type wells 202P to a ground voltage (Vss). While the adoption of the bottom isolation layer 215 may render tap cells useless, tap cell structures may still be present. In some embodiments represented in FIG. 14, tap cell transistors are omitted. In some alternative embodiments, tap cell transistors may be inserted between the protected transistor 10 and the fourth antenna transistor 20-4. Details of the tap cell transistors in these alternative embodiments have been described above and will not be repeated here.

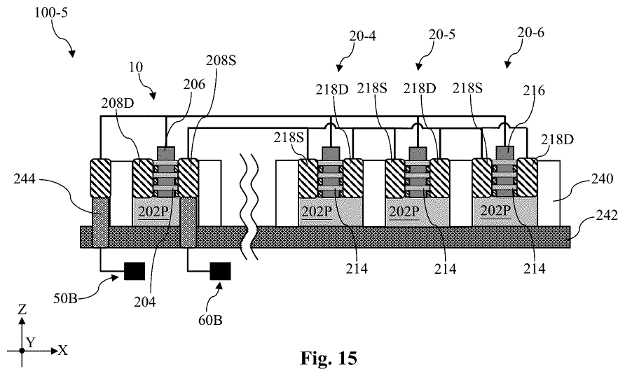

FIG. 15 illustrates a schematic cross-sectional view of the fifth PID prevention device 100-5 implemented with GAA transistors having backside contact structures. The protected transistor 10 in FIG. 15 is a GAA transistor that including first channel members 204 extending between a first source feature 208S and a first drain feature 208D. A first gate structure 206 wraps around each of the first channel members 204. A plurality of inner spacer features 230 interleave the first channel members 204 and space the first gate structure 206 from sidewalls of the first source feature 208S and the first drain feature 208D. In the depicted embodiments, the protected transistor 10 is an n-type GAA transistor disposed over a first p-type well 202P of a substrate 202. The first source feature 208S and the first drain feature 208 of the protected transistor 10 are in direct contact with the first p-type well 202P but the first p-type well 202P is insulated from other well regions. As shown in FIG. 15, the protected transistor 10 includes a SPR construction where the substrate is thinned such that neither a bulk substrate nor a common well is available to connect two well regions. Backside contacts 244 are formed through a backside dielectric layer 242 to couple to source/drain features, such as the first source feature 208S. Detailed description of the first p-type well 202P, the first source feature 208S, the first drain feature 208D, the first gate structure 206, and inner spacer features 230 have been provided above and will not be repeated here for brevity.

The fifth PID prevention device 100-5 in FIG. 15 includes multiple antenna transistors connected in a stacked gate configuration. For illustration purposes, the fifth PID prevention device 100-5 in FIG. 15 includes three antenna transistors—a fourth antenna transistor 20-4, a fifth antenna transistor 20-5 and a sixth antenna transistor 20-6. Each of the three antenna transistors includes second channel members 214 extending between a second source feature 218S and a second drain feature 218D along the X direction. A second gate structure 216 wraps around each of the second channel members 214. In the depicted embodiments, each of the fourth antenna transistor 20-4, the fifth antenna transistor 20-5 and the sixth antenna transistor 20-6 is an n-type GAA transistor disposed on different p-type wells that are separate from one another.

In some embodiments represented in FIG. 15, the second source features 218S and second drain features 218D of the fourth antenna transistor 20-4, the fifth antenna transistor 20-5 and the sixth antenna transistor 20-6 are electrically coupled to the first source feature 208S. The second gate structures 216 of the fourth antenna transistor 20-4, the fifth antenna transistor 20-5 and the sixth antenna transistor 20-6 are electrically coupled to the first gate structure 206. Additionally, the first gate structure 206 is electrically coupled to a first group of backside metal wiring structure 50B by way of a backside contact 244. The first group of backside metal wiring structure 50B may collect accumulated charges to cause damages to the protected transistor 10. The first source feature 208S is coupled to a second group of backside metal wiring structure 60B by way of a backside contact 244. When connected in the way shown in FIG. 15, the accumulated charge from first group of backside metal wiring structure 50B may cause a field stress shared among the first gate structure 206 and the second gate structures 216 of the fourth antenna transistor 20-4, the fifth antenna transistor 20-5 and the sixth antenna transistor 20-6. The distribution of field stress helps reduce or eliminate the high-field stress at the first gate structure 106.

Tap cells are common in standard cell designs and may be inserted into an IC device to serve as ways to pull the p-type wells 202P to a ground voltage (Vss). While the adoption of the SPR construction may render tap cells useless, tap cell structures may still be present. In some embodiments represented in FIG. 15, tap cell transistors are omitted. In some alternative embodiments, tap cell transistors may be inserted between the protected transistor 10 and the fourth antenna transistor 20-4. Details of the tap cell transistors in these alternative embodiments have been described above and will not be repeated here.

In one example aspect, the present disclosure provides a semiconductor structure. The semiconductor structure includes a first transistor that includes a first source feature, a first drain feature, and a first gate structure, a second transistor that includes a second source feature, a second drain feature, and a second gate structure. The first source feature is electrically coupled to the second source feature. The second drain feature is electrically coupled to the first gate structure.

In some embodiments, the second gate structure is electrically coupled to the second source feature. In some implementations, the second gate structure is electrically coupled to the second drain feature. In some implementations, the first transistor is disposed on a first doped well on a substrate and each the first source feature and the first drain feature is insulated from the first doped well by a first isolation layer. In some embodiments, the second transistor is disposed on a second doped well on the substrate and each the second source feature and the second drain feature is insulated from the second doped well by a second isolation layer. In some embodiments, the first doped well is insulated from the second doped well. In some embodiments, the semiconductor structure further includes a bottom dielectric layer. The first transistor and the second transistor are disposed on the bottom dielectric layer. In some instances, the first transistor further includes a plurality of nanostructures extending between the first source feature and the first drain feature. The first gate structure wraps around each of the plurality of nanostructures.

Another aspect of the present disclosure pertains to a semiconductor structure. The semiconductor structure includes a substrate, a first well region and a second well region on the substrate, a first transistor and a second transistor disposed over the first well region, and a third transistor and a fourth transistor disposed over the second well region. The first transistor includes a first source feature, a first drain feature, and a first gate structure. The second transistor includes a second source feature, a second drain feature, and a second gate structure. The third transistor includes a third source feature, a third drain feature, and a third gate structure. The fourth transistor includes a fourth source feature, a fourth drain feature, and a fourth gate structure. The first source feature is electrically coupled to the fourth source feature and the first gate structure is electrically coupled to the fourth drain feature.

In some embodiments, the second source feature, the second drain feature, the third source feature, and the third drain feature are electrically floating. In some embodiments, the second transistor is not electrically coupled to the third transistor. In some implementations, the first source feature, the first drain feature, the second source feature, and the second drain feature are insulated from the first well region. The third source feature, the third drain feature, the fourth source feature, and the fourth drain feature are insulated from the second well region. In some embodiments, the fourth gate structure is electrically coupled to the fourth source feature. In some implementations, the fourth gate structure is electrically coupled to the fourth drain feature. In some embodiments, the first transistor further includes a plurality of nanostructures extending between the first source feature and the first drain feature and the first gate structure wraps around each of the plurality of nanostructures.

Yet another aspect of the present disclosure pertains to a semiconductor structure. The semiconductor structure includes a dielectric layer, a first well region and a second well region over the dielectric layer, a first transistor disposed over the first well region, and a second transistor disposed over the second well region. The first transistor includes a first source feature, a first drain feature, and a first gate structure. The second transistor includes a second source feature, a second drain feature, and a second gate structure. The first source feature is electrically coupled to the second source feature. The first gate structure is electrically coupled to the second drain feature.

In some embodiments, the second gate structure is electrically coupled to the second source feature. In some embodiments, the second gate structure is electrically coupled to the second drain feature. In some instances, the semiconductor structure further includes a third well region and a fourth well region over the dielectric layer, a third transistor disposed over the third well region, and a fourth transistor disposed over the fourth well region. The first well region, the second well region, the third well region, and the fourth well region are insulated from one another. The third transistor and fourth transistor are not electrically connected. In some embodiments, the third well region and the fourth well region are disposed between the first well region and the second well region.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a first transistor comprising:
a first source feature,
a first drain feature, and
a first gate structure; and
a second transistor comprising:
a second source feature,
a second drain feature, and
a second gate structure,
wherein the first source feature is electrically coupled to the second source feature,
wherein the second drain feature is electrically coupled to the first gate structure.

2. The semiconductor structure of claim 1, wherein the second gate structure is electrically coupled to the second source feature.

3. The semiconductor structure of claim 1, wherein the second gate structure is electrically coupled to the second drain feature.

4. The semiconductor structure of claim 1,
wherein the first transistor is disposed on a first doped well on a substrate,
wherein each the first source feature and the first drain feature is insulated from the first doped well by a first isolation layer.

5. The semiconductor structure of claim 4,
wherein the second transistor is disposed on a second doped well on the substrate,
wherein each the second source feature and the second drain feature is insulated from the second doped well by a second isolation layer.

6. The semiconductor structure of claim 5, wherein the first doped well is insulated from the second doped well.

7. The semiconductor structure of claim 1, further comprising:
a bottom dielectric layer,
wherein the first transistor and the second transistor are disposed on the bottom dielectric layer.

8. The semiconductor structure of claim 1,
wherein the first transistor further comprises a plurality of nanostructures extending between the first source feature and the first drain feature,
wherein the first gate structure wraps around each of the plurality of nanostructures.

9. A semiconductor structure, comprising:
a substrate;
a first well region and a second well region on the substrate;
a first transistor and a second transistor disposed over the first well region; and
a third transistor and a fourth transistor disposed over the second well region,
wherein the first transistor comprises a first source feature, a first drain feature, and a first gate structure,
wherein the second transistor comprises a second source feature, a second drain feature, and a second gate structure,
wherein the third transistor comprises a third source feature, a third drain feature, and a third gate structure,
wherein the fourth transistor comprises a fourth source feature, a fourth drain feature, and a fourth gate structure,
wherein the first source feature is electrically coupled to the fourth source feature,
wherein the first gate structure is electrically coupled to the fourth drain feature.

10. The semiconductor structure of claim 9, wherein the second source feature, the second drain feature, the third source feature, and the third drain feature are electrically floating.

11. The semiconductor structure of claim 9, wherein the second transistor is not electrically coupled to the third transistor.

12. The semiconductor structure of claim 9,
wherein the first source feature, the first drain feature, the second source feature, and the second drain feature are insulated from the first well region,
wherein the third source feature, the third drain feature, the fourth source feature, and the fourth drain feature are insulated from the second well region.

13. The semiconductor structure of claim 9, wherein the fourth gate structure is electrically coupled to the fourth source feature.

14. The semiconductor structure of claim 9, wherein the fourth gate structure is electrically coupled to the fourth drain feature.

15. The semiconductor structure of claim 9,
wherein the first transistor further comprises a plurality of nanostructures extending between the first source feature and the first drain feature,
wherein the first gate structure wraps around each of the plurality of nanostructures.

16. A semiconductor structure, comprising:
a dielectric layer;
a first well region and a second well region over the dielectric layer;
a first transistor disposed over the first well region; and
a second transistor disposed over the second well region;
wherein the first transistor comprises a first source feature, a first drain feature, and a first gate structure,
wherein the second transistor comprises a second source feature, a second drain feature, and a second gate structure,
wherein the first source feature is electrically coupled to the second source feature,
wherein the first gate structure is electrically coupled to the second drain feature.

17. The semiconductor structure of claim 16, wherein the second gate structure is electrically coupled to the second source feature.

18. The semiconductor structure of claim 16, wherein the second gate structure is electrically coupled to the second drain feature.

19. The semiconductor structure of claim 16, further comprising:
a third well region and a fourth well region over the dielectric layer;
a third transistor disposed over the third well region; and
a fourth transistor disposed over the fourth well region,
wherein the first well region, the second well region, the third well region, and the fourth well region are insulated from one another,
wherein the third transistor and fourth transistor are not electrically connected.

20. The semiconductor structure of claim 19, wherein the third well region and the fourth well region are disposed between the first well region and the second well region.
